(19) United States
(12) Patent Application Publication
(10) Pub. No.: US 2025/0391803 A1
(43) Pub. Date: Dec. 25, 2025

(54) METHOD FOR PRODUCING A SEMICONDUCTOR ASSEMBLY COMPRISING A SEMICONDUCTOR ELEMENT AND A SUBSTRATE, AND CORRESPONDING DEVICE

(71) Applicant: Siemens Aktiengesellschaft, 80333 München (DE)

(72) Inventor: JENS SCHMENGER, Forchheim (DE)

(73) Assignee: Siemens Aktiengesellschaft, 80333 München (DE)

(21) Appl. No.: 18/879,605

(22) PCT Filed: May 5, 2023
(86) PCT No.: PCT/EP2023/061982

§ 371 Date: Dec. 27, 2024

(30) Foreign Application Priority Data
Jun. 29, 2022 (EP) 22181749.7

(51) Int. Cl. H01L 23/00; H01L 21/56; H01L 23/31; H01L 23/538; H01L 25/07

(52) U.S. Cl. CPC H01L 24/37; H01L 21/56; H01L 23/3121; H01L 23/538; H01L 24/32; H01L 24/40; H01L 24/84; H01L 25/072; H01L 24/48; H01L 24/73; H01L 2224/32225; H01L 2224/3701; H01L 2224/40225; H01L 2224/40491; H01L 2224/48225; H01L 2224/73221; H01L 2224/73263; H01L 2224/73265; H01L 2224/84201; H01L 2924/13055

(57) ABSTRACT

In a method for producing a semiconductor assembly, a first load contact of a semiconductor element materially bonded to a first metallization of a substrate and a molded metal body is materially bonded to a second load contact of the semiconductor element, with the second load contact being arranged on a face of the semiconductor element facing away from the substrate. A contacting element is contacted to the second load contact of the semiconductor element via the molded metal body, with the contacting element being embodied as a metal sheet and profiled such as to form a plurality of contact points. The profiled contacting element is pressed against the semiconductor element via a housing cover, wherein the profiled contacting element is contacted to the first metallization of the substrate to connect the second load contact.

The invention relates to a method for producing a semiconductor assembly comprising a semiconductor element and a substrate.

The invention furthermore relates to a semiconductor assembly comprising a semiconductor element and a substrate.

In addition, the invention relates to a power converter comprising at least one such semiconductor assembly.

Such a semiconductor module assembly is generally used in a power converter. A power converter should, for example, be understood as being a rectifier, an inverter, a converter or a DC-to-DC converter. The semiconductor elements used in the semiconductor module assembly are, inter alia, transistors, diodes, TRIACs or thyristors. The transistors are, for example, embodied as insulated gate bipolar transistors (IGBTs), field effect transistors or bipolar transistors. Such transistors can comprise a control contact and load contacts. Semiconductor elements are usually contacted via bonding wires, which in particular contain aluminum.

The published patent application EP 3 958 306 A1 describes a power module comprising at least two power semiconductor assemblies contacted on a substrate and arranged in a housing. In order to improve the reliability of the power module, it is proposed that the power semiconductor assemblies in each case have at least one semiconductor component, wherein the housing has power connectors on opposite sides, wherein the substrate has leads from the power connectors to the power semiconductor assemblies, wherein the leads are arranged on the substrate in such a way that electrical current is provided in a symmetrical manner.

The published patent application WO 2022/002464 A1 describes a power module comprising at least two power units which in each case comprise at least one power semiconductor and a substrate. In order to reduce the installation space required for the power module and improve heat dissipation, it is proposed that the at least one power semiconductor is in each case connected, in particular in a materially bonded manner, to the respective substrate, wherein the substrates of the at least two power units are in each case directly connected in a materially bonded manner to a surface of a common heat sink.

The patent DE 20 2012 004 434 U1 describes a molded metal body for creating a connection of a power semiconductor with top-side potential surfaces to thick wires or ribbons, wherein at least one segment is divided off by a molded metal body which projects over one or more surfaces and from which at least one segment is electrically separated from the remaining molded metal body, said segment extending from a contacting section to a potential surface of the power semiconductor to a fastening section for thick wires laterally spaced apart therefrom.

In particular for ever-larger currents that are impressed into the chip with a constant chip area, commonly used bonding wires reach their limits, for example with regard to load cycle durability.

Against this background, it is an object of the present invention to disclose a semiconductor assembly with improved reliability.

This object is achieved according to the invention by a method for producing a semiconductor assembly comprising a semiconductor element and a substrate, having the following steps: materially bonding a first load contact of the

semiconductor element to a first metallization of the substrate, materially bonding a molded metal body to a second load contact of the semiconductor element, said second load contact being arranged on a face of the semiconductor element facing away from the substrate, contacting a profiled contacting element, which is embodied as a metal sheet, to the second load contact of the semiconductor element via the molded metal body, wherein a plurality of contact points is formed by means of the profiling and the profiled contacting element is pressed against the semiconductor element via a housing cover, wherein, to connect the second load contact (8), the profiled contacting element (22) is contacted to the first metallization (10) of the substrate (12).

Furthermore, the object is achieved according to the invention by a semiconductor assembly comprising a semiconductor element and a substrate, wherein the semiconductor element has a first load contact and a second load contact, wherein the first load contact is connected in a materially bonded manner to a first metallization of the substrate, wherein a molded metal body is connected in a materially bonded manner to the second load contact, wherein a profiled contacting element, which is embodied as a metal sheet, is contacted to the second load contact via the molded metal body (20), said second load contact being arranged on a face of the semiconductor element facing away from the substrate, wherein a plurality of contact points is formed by means of the profiling, wherein the profiled contacting element is pressed against the semiconductor element via a housing cover, wherein, to connect the second load contact, the profiled contacting element is contacted to the first metallization of the substrate.

In addition, the object is achieved according to the invention by a power converter comprising at least one such semiconductor assembly.

The advantages and preferred embodiments listed below in respect of the semiconductor assembly can be transferred analogously to the power converter and the method.

The invention is based on the idea of improving the load cycle durability of a semiconductor assembly by improved contacting of semiconductor elements. A first load contact of the semiconductor element is connected in a materially bonded manner to a first metallization of a substrate. The first metallization of the substrate can be embodied as structured and arranged on a dielectric layer, which, inter alia, can contain a ceramic material such as aluminum nitride or aluminum oxide or an organic material. For example, the first metallization is embodied as copper cladding. The materially bonded connection of the semiconductor element to the first metallization can, inter alia, be produced by soldering, sintering, or also by an adhesive connection, for example with an electrically and thermally conductive adhesive.

A profiled contacting element is then contacted to a second load contact, which is arranged on a face of the semiconductor elements facing away from the substrate, as is usual, for example, with a vertical power semiconductor, in particular an IGBT, wherein a plurality of contact points is formed by means of the profiling. In particular, the profiled contacting element is contacted loosely on the semiconductor element, i.e., without a materially bonded connection. The contacting element can, inter alia, be embodied as a metal sheet, in particular a spring sheet, which can be alternately periodically profiled in the region of the contacting to the second load contact. Alternately periodic profiling can, inter alia, comprise an infinitely continuous sequence of interconnected point-symmetrical individual types of profiling. Alternately periodic profiling is, for example, a substantially sinusoidal waveform. The contacting element can, for example, be configured to contact the first metallization of the substrate or guided to an external connector.

In a further step, the profiled contacting element is pressed against the semiconductor element via a housing cover. For example, a housing cover made of a dielectric material, in particular a polymer, exerts a force on the profiling of the contacting element that is orthogonal to the second load contact. Subjecting the contacting element to pressure causes it to be deformed, in particular elastically deformed. Such contacting elements have high current-carrying capacity and in particular improve the load cycle durability of the semiconductor assembly. This results in improved reliability. In addition, the architecture of the semiconductor assembly is largely retained, in particular compared to a standard bonding process and such a production process can be easily and inexpensively integrated into a standard series production process.

A molded metal body is connected in a materially bonded manner to the second load contact of the semiconductor element before the profiled contacting element is contacted. The profiled contacting element is contacted to the second load contact of the semiconductor element via the molded metal body. The molded metal body can be embodied as a metal sheet, which can, inter alia, contain copper, aluminum, silver, gold, molybdenum or an alloy thereof. The materially bonded connection of the semiconductor element to the molded metal body can, inter alia, be produced by soldering, sintering, or also by an adhesive connection, for example with an electrically and thermally conductive adhesive. Alternatively, the molded metal body can be applied to the second load contact of the semiconductor element by means of an additive method, in particular by means of a thermal spraying process, such as cold gas spraying, and in this way be connected in a materially bonded manner to the second load contact of the semiconductor element. The molded metal body distributes a pressure created by the plurality of contact points onto the semiconductor element. This ensures a more even pressure distribution, particularly in the case of thermal load fluctuations occurring during operation, so that, for example, the semiconductor element is prevented from breaking. Thus, the molded metal body improves the reliability of the semiconductor assembly.

A further embodiment provides that the semiconductor assembly is encapsulated after the pressing. An encapsulating compound containing silicone, for example, ensures that the required voltage clearances are maintained. Furthermore, such encapsulation serves to protect against harmful environmental influences.

A further embodiment provides that the profiled contacting element is contacted directly on the molded metal body. Direct contacting is achieved without any further connecting means such as soldering tin or adhesive. Such contacting is simple and reliable, in particular in combination with the pressing.

A further embodiment provides that the profiled contacting element is predominantly elastically deformed during the pressing. For example, the profiled contacting element contains an elastic copper alloy such as CuZn37, CuSn6, CuNiI8Zn20, copper beryllium or a spring steel. Predominantly elastic deformation ensures sufficient contact pressure, even during load changes and temperature fluctuations, thus achieving improved reliability. Furthermore, differences in height between the semiconductor element and substrate and any tilting of the semiconductor element can be compensated and this likewise has a positive effect on the reliability of the semiconductor assembly.

A further embodiment provides that a plurality of contact points is formed by means of S-shaped or trapezoidal profiling of the profiled contacting element. Such profiling is simple and inexpensive to produce. Furthermore, such profiling achieves homogeneous force and heat distribution and heat spreading of the chip surface.

A further embodiment provides that, to connect the second load contact, in particular in a materially bonded manner, the profiled contacting element is connected to a first metallization of the substrate. The materially bonded connection can, inter alia, be produced by soldering, sintering, or also by adhesion, for example with an electrically and thermally conductive adhesive. Such an arrangement is simple and inexpensive to realize.

A further embodiment provides that, to connect the second load contact, the profiled contacting element is pressed onto the first metallization of the substrate via the housing cover. This type of connection achieves improved reliability, in particular with frequent load changes and temperature fluctuations.

The following describes and explains the invention in more detail with reference to the exemplary embodiments depicted in the figures.

It is shown in:

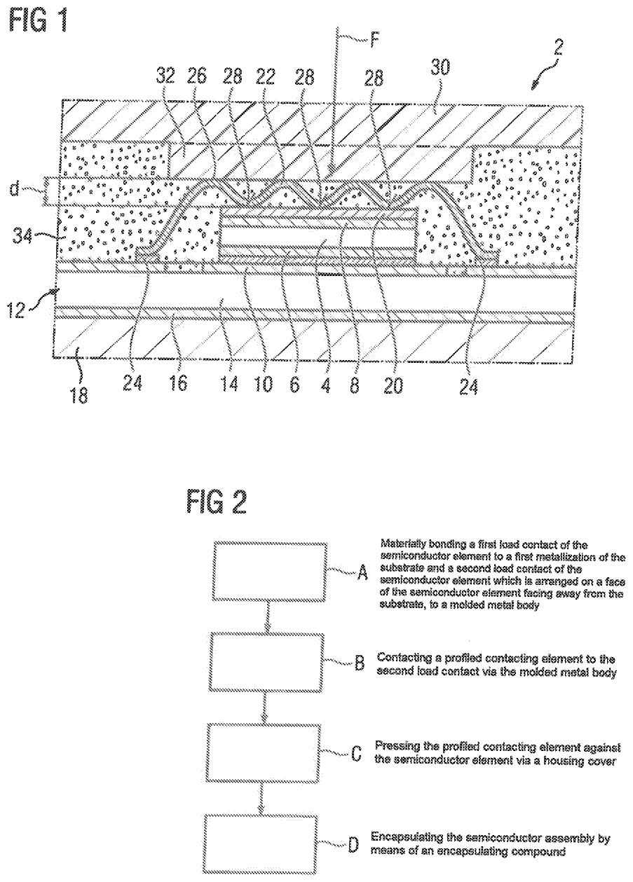

FIG. 1 a schematic cross-sectional view of a first embodiment of a semiconductor assembly,

FIG. 2 a flow chart of a method for producing a semiconductor assembly,

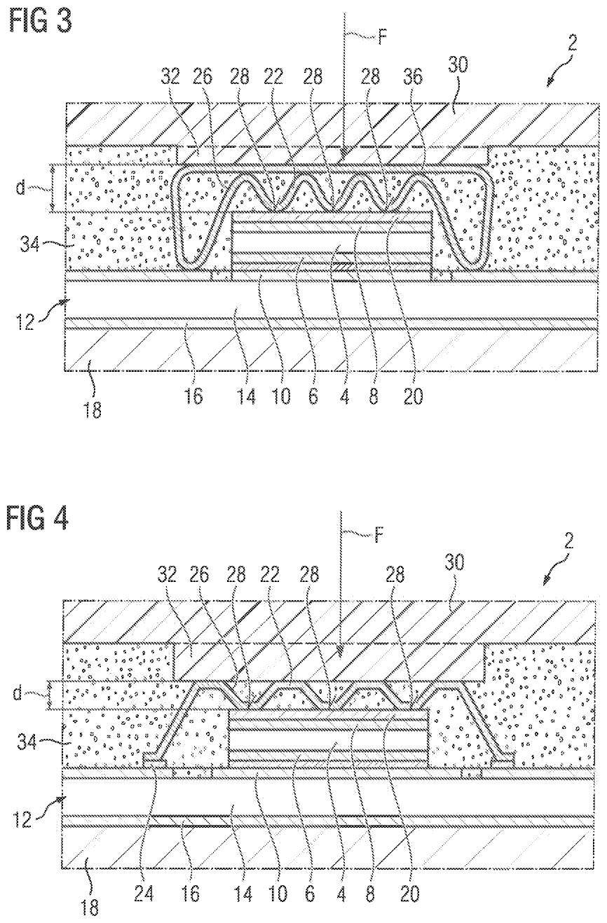

FIG. 3 a schematic cross-sectional view of a second embodiment of a semiconductor assembly,

FIG. 4 a schematic cross-sectional view of a third embodiment of a semiconductor assembly,

FIG. 5 a schematic perspective view of a fourth embodiment of a semiconductor assembly,

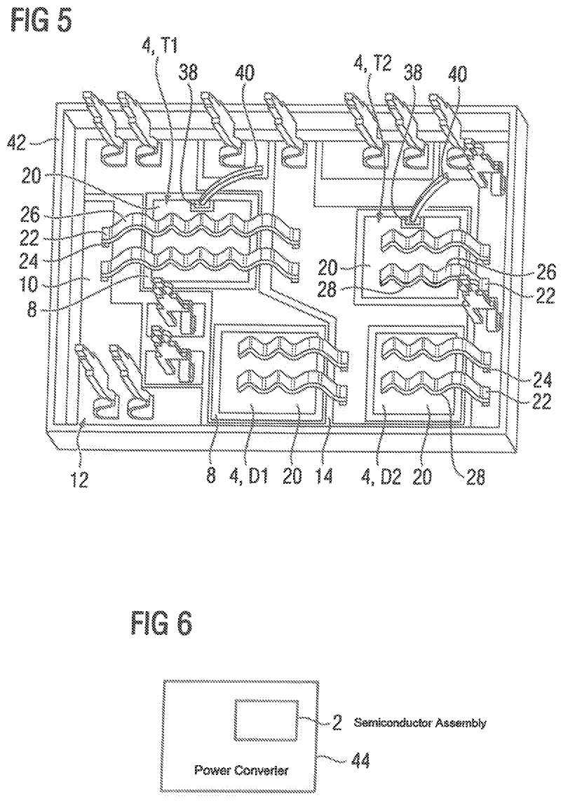

FIG. 6 a schematic view of a power converter.

The exemplary embodiments explained below are preferred embodiments of the invention. In the exemplary embodiments, the described components of the embodiments in each case represent individual features of the invention, which are to be regarded as being independent of one another and which the invention further develops in each case also independently of one another and are therefore to be viewed as part of the invention individually or in a combination other than that shown. Furthermore, the described embodiments can also be supplemented by further features of the invention already described.

In the different figures, the same reference symbols have the same meaning.

FIG. 1 is a schematic cross-sectional view of a first embodiment of a semiconductor assembly 2 comprising a semiconductor element 4 embodied as a vertical power transistor, in particular as an insulated gate bipolar transistor (IGBT). Further examples of such semiconductor elements 4 are TRIACs, thyristors, diodes or other types of transistors, such as field effect transistors and bipolar transistors. The semiconductor element 4 has a first load contact 6 and a second load contact 8; for reasons of clarity, a control contact is not depicted in FIG. 1.

The first load contact 6 of the semiconductor element 4 is connected in a materially bonded manner to a structured first metallization 10 of a substrate 12. The materially bonded connection of the semiconductor element 4 to the substrate 12 can, inter alia, be produced by a soldered connection and/or a sintered connection, or also by an adhesive connection, for example with an electrically and thermally conductive adhesive. In addition, the substrate 12 has a dielectric material layer 14 and a second metallization 16 arranged on a face of the substrate 12 facing away from the metallization 10. The dielectric material layer 14 can, inter alia, contain a ceramic material, in particular aluminum nitride or aluminum oxide, or an organic material. Furthermore, the substrate 12 is connected, in particular in a materially bonded manner, to a heat sink 18 via the second metallization 16, so that the semiconductor element 4 is in an electrically insulated and thermally conductive connection with the heat sink 18 via the substrate.

The second load contact 8 of the semiconductor element 4, which is arranged on a face of the semiconductor element 4 facing away from the substrate 12, is connected in a materially bonded manner to a molded metal body 20, which acts as a buffer layer. For example, the molded metal body 20 is embodied as a metal sheet, in particular as a copper sheet, which is connected to the control-contact contact surface via a sintered connection. Furthermore, the metal sheet can have a coating on one side or both sides, for example to produce a bond connection. Such a coating can, inter alia, contain aluminum, silver, gold, zinc or an alloy thereof. Alternatively, the molded metal body 20 can be applied by means of an additive method, in particular by means of a thermal spraying process, such as cold gas spraying.

Furthermore, a profiled contacting element 22 produced from a metallic material is contacted directly to the second load contact 8 via the molded metal body 20, i.e., without further connecting means. By way of example, the profiled contacting element 22 is attached to both sides of the first metallization 10 of the substrate 12 via a materially bonded connection 24. The materially bonded connection 24 can, inter alia, be produced by sintering, soldering or a welding process. In addition, in the region of the contacting to the second load contact 8, the contacting element 22 has S-shaped profiling 26 which is predominantly elastically deformable. For example, the profiled contacting element 22 contains an elastic copper alloy such as CuZn37, CuSn6, CuNiI8Zn2O, copper beryllium or a spring steel. A plurality of substantially linear contact points 28 to the load contact 8 is formed by means of the S-shaped profiling 26. In particular, the contacting element 22 is embodied as a spring sheet which is profiled in a wave shape in the region of the contacting to the second load contact 8.

A force F acts on the S-shaped profiling 26 of the contacting element via a housing cover 30 which is made of a dielectric material, for example a polymer. In particular, the force F is directed so as to act orthogonally to the second load contact 8. The housing cover 30 is not deformed noticeably compared to the profiled contacting element 22. Thus, the profiled contacting element 22 is pressed against the semiconductor element 4 by the housing cover 30. In order to exert a defined force F onto the contacting element 22 via the housing cover, a defined distance d is established above the semiconductor element 4. The establishment of the defined distance d to the semiconductor element 4 is realized by way of example in FIG. 1 by a projection 32. Alternatively, the housing cover 30 can be embodied in two parts with a pressure element, in particular a rectangular pressure element or, depending on the profiling 26 of the contacting element 22, have a recess. In addition, the semiconductor assembly 2 is encapsulated between the housing cover 30 and substrate 12 by means of an encapsulating compound 34, which contains silicone, for example, and serves to maintain the required voltage clearances and to protect against harmful environmental influences.

FIG. 2 is a flow chart of a method for producing a semiconductor assembly 2, which is, for example, embodied as depicted in FIG. 1 and comprises a semiconductor element 4 and a substrate 12. The method comprises materially bonding A a first load contact 6 of the semiconductor element 4 to a first metallization 10 of the substrate 12 and a second load contact 8 of the semiconductor element 4, which is arranged on a face of the semiconductor element 4 facing away from the substrate 12, to a molded metal body 20.

In a further step, a profiled contacting element 22 is contacted B to the second load contact 8 via the molded metal body 20, wherein a plurality of contact points 28 is formed by means of the profiling 26. The profiled contacting element 22 is contracted directly on the molded metal body 20.

In a further step, the profiled contacting element 22 is pressed C against the semiconductor element 4 via a housing cover 30, wherein the profiled contacting element 22 is predominantly elastically deformed during the pressing C. After the pressing C, the semiconductor assembly is encapsulated 4 by means of an encapsulating compound 34.

FIG. 3 is a schematic cross-sectional view of a second embodiment of a semiconductor assembly 2. The profiled contacting element 22 is embodied as a spring sheet with a closed cross section, which has S-shaped profiling 26 and, running parallel thereto, a straight section 36, wherein the straight section 36 is contacted directly in a planar manner to the projection 32 of the housing cover 32. The S-shaped profiling 26 of the contacting element 22 is pressed by the projection 32 of the housing cover 32 onto the molded metal body 20 and on both sides onto the first metallization 10 of the substrate 12. In this way, the second load contact 8 of the semiconductor element 4 is contacted to the first metallization 10 of the substrate 12 without a materially bonded connection and without connecting means such as a soldering tin, sinter paste or adhesive. The further embodiment of the semiconductor assembly 2 in FIG. 3 corresponds to that in FIG. 1.

FIG. 4 is a schematic cross-sectional view of a third embodiment of a semiconductor assembly 2, wherein the contacting element 22 has trapezoidal profiling 26 in the region of the contacting to the second load contact 8. The further embodiment of the semiconductor assembly 2 in FIG. 4 corresponds to that in FIG. 1.

FIG. 5 is a schematic perspective view of a fourth embodiment of a semiconductor assembly 2 comprising semiconductor elements 4 embodied as transistors T1, T2 and diodes D1, D2. The transistors T1, T2 which are embodied as IGBTs by way of example, in each case have a control contact 38, which is in each case connected to the first metallization 10 of the substrate 12 via a bonding wire 40. A housing frame 42 completely surrounds the substrate 12. An encapsulating compound, which is delimited by the housing frame 42, and a housing cover, which the profiled contacting elements 22 onto the respective molded metal body 20 of the semiconductor elements 4, are not shown in FIG. 5 for reasons of clarity. The housing cover is attached to the housing frame 42 by means of screws. The further embodiment of the semiconductor assembly 2 in FIG. 5 corresponds to that in FIG. 1.

FIG. 6 is a schematic view of a power converter 44, which comprises a semiconductor assembly 2 by way of example.

In summary, the invention relates to a method for producing a semiconductor assembly 2 comprising a semiconductor element 4 and a substrate 12. In order to improve the reliability of the semiconductor assembly 2, the following steps are proposed: materially bonding A a first load contact 6 of the semiconductor element 4 to a first metallization 10 of the substrate 12, contacting B a profiled contacting element 22 to a second load contact 8 of the semiconductor element 4, said second load contact being arranged on a face of the semiconductor element 4 facing away from the substrate 12, wherein a plurality of contact points 28 are formed by means of the profiling 26, pressing C the profiled contacting element 22 against the semiconductor element 4 via a housing cover 30.

1.-18. (canceled)

19. A method for producing a semiconductor assembly, the method comprising:
materially bonding a first load contact of a semiconductor element to a first metallization of a substrate;
materially bonding a molded metal body to a second load contact of the semiconductor element, with the second load contact being arranged on a face of the semiconductor element facing away from the substrate;
contacting a contacting element to the second load contact of the semiconductor element via the molded metal body, with the contacting element being embodied as a metal sheet and profiled such as to form a plurality of contact points;
pressing the profiled contacting element against the semiconductor element via a housing cover,
wherein the profiled contacting element is contacted to the first metallization of the substrate to connect the second load contact.

20. The method of claim 19, wherein the profiled contacting element is alternately periodically profiled in a region of contacting to the second load contact.

21. The method of claim 19, further comprising encapsulating the semiconductor assembly after the profiled contacting element has been pressed against the semiconductor element.

22. The method of claim 19, wherein the profiled contacting element is contacted directly on the molded metal body.

23. The method of claim 19, wherein the profiled contacting element is predominantly elastically deformed as the profiled contacting element is pressed against the semiconductor element.

24. The method of claim 19, wherein the plurality of contact points is formed by an S-shaped or trapezoidal profiling of the profiled contacting element.

25. The method of claim 19, wherein the profiled contacting element is connected to the first metallization of the substrate so as to connect the second load contact.

26. The method of claim 25, wherein the profiled contacting element is connected to the first metallization of the substrate in a materially bonded manner.

27. The method of claim 19, further comprising pressing the profiled contacting element onto the first metallization of the substrate via the housing cover so as to connect the second load contact.

28. A semiconductor assembly, comprising:
a substrate;
a semiconductor element comprising a first load contact which is connected in a materially bonded manner to a first metallization of the substrate, and a second load contact arranged on a face of the semiconductor element facing away from the substrate;
a molded metal body connected to the second load contact of the semiconductor element in a materially bonded manner;
a contacting element embodied as a metal sheet and designed to contact to the second load contact via the molded metal body, said contacting element being profiled such as to form a plurality of contact points and contacted to the first metallization of the substrate to connect the second load contact; and
a housing cover designed to press the profiled contacting element against the semiconductor element.

29. The semiconductor assembly of claim 28, wherein the profiled contacting element is alternately periodically profiled in a region of contacting to the second load contact.

30. The semiconductor assembly of claim 28, further comprising an encapsulating compound for encapsulating the semiconductor assembly.

31. The semiconductor assembly of claim 28, wherein the profiled contacting element is contacted directly on the molded metal body.

32. The semiconductor assembly of claim 28, wherein the profiled contacting element is predominantly elastically deformed as the profiled contacting element is pressed against the semiconductor element via the housing cover.

33. The semiconductor assembly of claim 28, wherein the profiled contacting element is embodied as a spring sheet.

34. The semiconductor assembly of claim 28, wherein the profiled contacting element is profiled at least partially by an S-shaped or trapezoidal profiling.

35. The semiconductor assembly of claim 28, wherein the profiled contacting element is connected to the first metallization of the substrate so as to connect the second load contact.

36. The semiconductor assembly of claim 35, wherein the profiled contacting element is connected to the first metallization of the substrate in a materially bonded manner.

37. The semiconductor assembly of claim 28, wherein the profiled contacting element is pressed onto the first metallization of the substrate via the housing cover so as to connect the second load contact.

38. A power converter, comprising a semiconductor assembly, said semiconductor assembly comprising a substrate, a semiconductor element comprising a first load contact which is connected in a materially bonded manner to a first metallization of the substrate, and a second load contact arranged on a face of the semiconductor element facing away from the substrate, a molded metal body connected to the second load contact of the semiconductor element in a materially bonded manner, a contacting element embodied as a metal sheet and designed to contact to the second load contact via the molded metal body, said contacting element being profiled such as to form a plurality of contact points and contacted to the first metallization of the substrate to connect the second load contact, and a housing cover designed to press the profiled contacting element against the semiconductor element.
